(19) United States
(12) Patent Application Publication
(10) Pub. No.: US 2020/0183468 A1
(43) Pub. Date: Jun. 11, 2020

(54) Modular Cooling Panel

(71) Applicants: Garrett Christopher Lloyd, Indianapolis, IN (US); Adam Corey Pirtle, Bloomington, IN (US); Leighton Garrison Lindman, Indianapolis, IN (US); Matthew Adrian McDonald, Pittsboro, IN (US); Kieran Connor Drexler, Martinsville, IN (US)

(72) Inventors: Garrett Christopher Lloyd, Indianapolis, IN (US); Adam Corey Pirtle, Bloomington, IN (US); Leighton Garrison Lindman, Indianapolis, IN (US); Matthew Adrian McDonald, Pittsboro, IN (US); Kieran Connor Drexler, Martinsville, IN (US)

(21) Appl. No.: 16/211,649

(22) Filed: Dec. 6, 2018

(51) Int. Cl. G06F 1/20; H05K 7/20

(52) U.S. Cl. CPC G06F 1/203; G06F 1/189; H05K 7/20181

(57) ABSTRACT

A modular zone cooling system including a housing. The housing has air permeable mesh on a top and bottom surface. Each zone comprises at least a single fan coupled to at least a single temperature sensor. The fans and temperature sensors are coupled to a microcontroller that will in turn calculate the necessary speed of the fan to cool the zone to a desired temperature. A modular panel will contain a plurality of these zones which in turn can be coupled to other modular panels for expansion of the cooling system.

### TECHNICAL FIELD

The present disclosure generally relates to the cooling of portable and stationary electronic devices, and in particular, to a method of externally cooling these devices in an intelligent and efficient automated way.

### BACKGROUND

This section introduces aspects that may help facilitate a better understanding of the disclosure. Accordingly, these statements are to be read in this light and are not to be understood as admissions about what is or is not prior art.

Traditional methods of cooling electronic components or machines are usually in the form of internal cooling systems. For example, a portable computer will have internal fans to promote airflow to the inner electronic components by removing hot air and replacing it with cooler air from the surrounding area. Similarly, desktop computers work in the same way with larger components. With the ever increasing performance of small portable electronic devices the internal temperature becomes more critical for the overall performance of the device, and to avoid damage to the fragile internal components. Whether those be soldering joints, conductive gels, processors, internal batteries or any devices that are temperature sensitive. The current methods of cooling for these devices typically use single or multiple fan systems which are controlled using an internal thermostat inside the device. These systems are powered through the device itself. This creates an issue when trying to minimize the size of the devices while keeping up with ever increasing performance levels. The smaller the device, the smaller the fans have to be, there for reducing the volume of air that can be delivered to aid in cooling the device. To counteract this reduction in air volume (essentially mass flow rate) the fan must then be raised to higher speeds. Which is less than ideal due to the fact that the internal cooling components are powered by the device itself, therefore increasing load, which causes shorter battery life and raises the internal temperature of the device. Another common trait of these internal cooling systems is that they can be limited in the space that they deliver air within the device. Often times the most critical components receive a majority of the airflow while other components will receive less airflow.

Therefore, there is an unmet need for a novel approach to aid in the efficient and effective cooling of electronic devices while keeping the load removed from the device itself.

### SUMMARY

The intent of this invention is to provide a universal cooling system for electronic devices that prevents damage due to overheating, is easy to use and may be manufactured at a low cost. According to the present invention, there is provided a cooling panel having an air permeable mesh on both its top and bottom surfaces that is divided into multiple cooling zones comprising at least one fan per zone and at least one temperature sensor per zone, as well as an attached controller with connections to each of the temperature sensors and fans contained therein. These and other objects and features of the present invention will become more apparent from the following detailed description with reference to the accompanying drawings.

### BRIEF DESCRIPTION OF DRAWINGS

FIG. 1 is a top view of a zone cooling system, including an air permeable mesh on a top side, according to the present disclosure.

FIG. 2 is a side view of the zone cooling system of FIG. 1 showing two fans, according to the present disclosure.

FIG. 3 is an exploded perspective view of the zone cooling system showing a plurality of fans, temperature sensors, air permeable meshes for top and bottom sides, and a housing, according to the present disclosure.

FIG. 4 is an exploded side view showing the temperature sensors, the fans, and the housing and the air permeable mesh on the bottom and top sides, according to the present disclosure.

FIG. 5 is flowchart of operational logic for operating the zone cooling system of the present disclosure.

FIG. 6 is block diagram depicting various components in the zone cooling system of the present disclosure.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

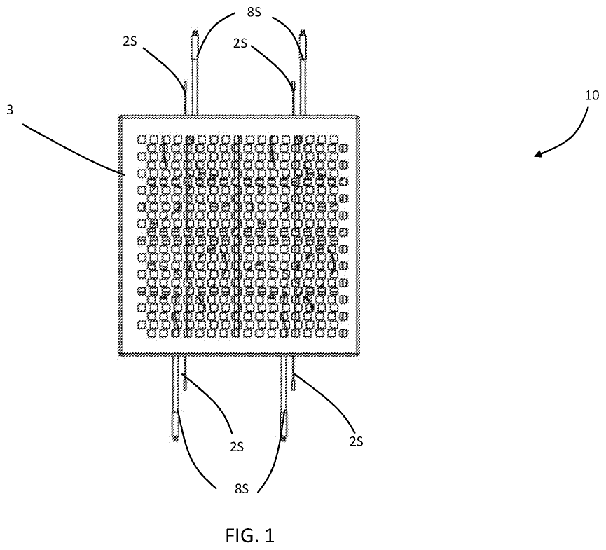

FIG. 1 is a top view of a zone cooling system 10, including an air permeable top surface 3, four temperature sensor wire connections 2S, and four DC electric motor wire connections 8S can be seen extruding from the entirety of the zone cooling system 10.

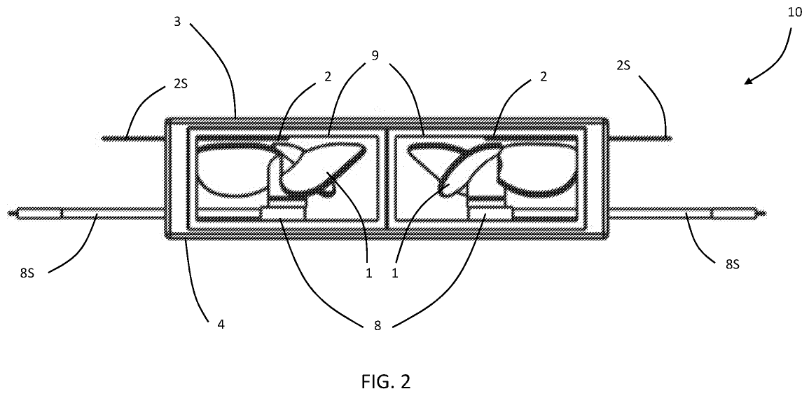

FIG. 2 is a side view of the zone cooling system 10, showing two fans 1, two DC electric motors 8, two DC electric motor wire connections 8S, two temperature sensors 2, two temperature sensor wire connections 2S, two fan housings 9, a top air permeable surface 3, and a bottom air permeable surface 4.

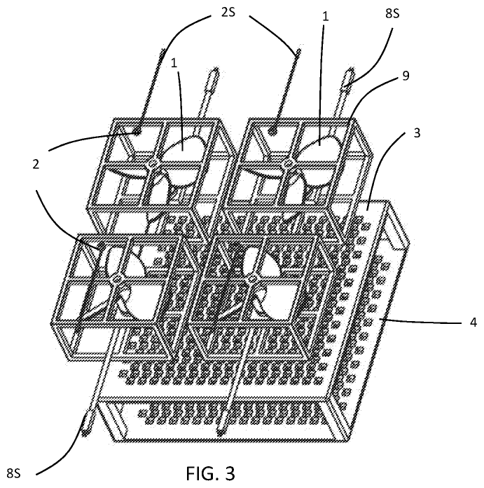

FIG. 3 is an exploded perspective view of the zone cooling system 10 showing four fans 1, four temperature sensors 2, four temperature sensor wire connections 2S, four DC electric motor wire connections 8S, four fan housings 9, a top air permeable surface 3, and bottom air permeable surface 4.

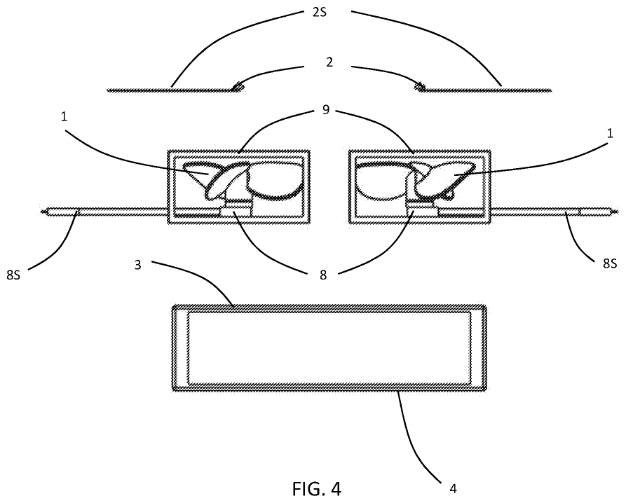

FIG. 4 is an exploded side view of the zone cooling system 10 showing two temperature sensors 2, two temperature sensor wire connections 2S, two fan housings 9, two fans 1, two DC electric motors 8, two DC electric motor wire connections 8S, a top air permeable surface 3 and a bottom air permeable surface 4.

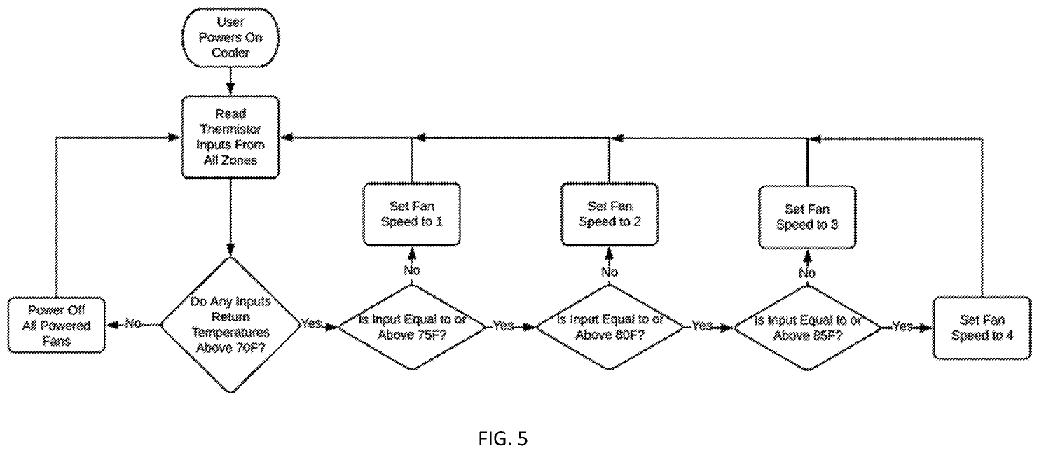

FIG. 5 Depicts a logic diagram in the form of a flow chart. The microcontroller 5 will be programmed to follow this logic in order to appropriately operate the cooling system 10. The diagram illustrates the microcontroller 5 receiving inputs from the temperature sensors 2 and comparing said inputs to a series of inequalities which serve to determine the magnitude of the temperature inputs. Each set of inequalities serve as a temperature range for various fan speed settings which are numbered 1 through 4 with 4 being the fastest fan speed. Once the magnitude of the temperature is determined, the microcontroller 5 will set each fan 1 at an appropriate fan speed as determined by the temperature magnitude of its zone.

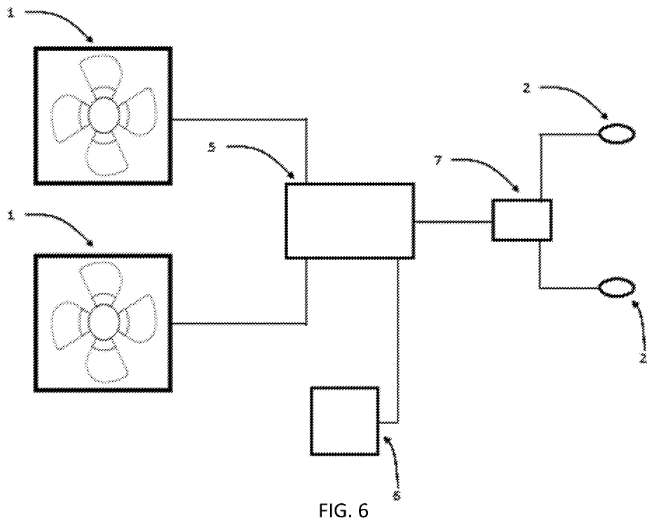

FIG. 6 Depicts the wiring diagram of the cooling system 10. The central component of the wiring diagram is a microcontroller 5 that will be programmed to follow the logic defined in the flowchart of FIG. 5. The microcontroller 5 is to be powered via connection to a power source 6. The temperature interface 7 receives power from the microcontroller 5 and inputs from the temperature sensors 2 which are then stabilized and forwarded to the microcontroller 5 for processing. The microcontroller 5 interprets the inputs received from the temperature sensors 2 and applies them to the logic of FIG. 5 which prompts the microcontroller to output fan speed settings to each individual fan 1 in the corresponding zone of the temperature sensor data. Fans 1 are to receive variable power from microcontroller 5 in the form of fan speed settings 1-4 with fan speed 4 being the maximum power.

A horizontal top surface 3 having a plurality of holes penetrating through its surface is attached directly above to an identical horizontal surface while allowing for a sufficient gap in between the two horizontal surfaces 3 and 4.

Fixed within the gap between the surfaces 3 and 4 is a fan housing 9. Which will be constructed as frame with no enclosed sides, having cross member supports on both the bottom and top surfaces. The top surface having a hole centrally located.

Fixed to the top of the fan housing 9 within the centrally located hole will be a temperature sensor 2 with wires extending out to an electrical connector 2S.

Fixed within the fan housing 9 is a fan 1 the fan having multiple extruding fins able to rotate axially around its center allowing for the movement of air in either direction dependent on the rotational direction of the fan.

Fixed to the fan is a DC electric motor 8 which will be used to rotate the fan 1. connected to the DC motor is an electrical wire with an electronic connector 8S providing electrical power to the DC electric motor 8.

Those having ordinary skill in the art will recognize that numerous modifications can be made to the specific implementations described above. The implementations should not be limited to the particular limitations described. Other implementations may be possible.

| | |
|---|---|
| Fan disposed in each of the plurality of zones | 1 |
| Temperature sensor disposed in each of the plurality of zones | 2 |
| Cooling panel having an air permeable mesh on a top surface | 3 |
| Cooling panel having an air permeable mesh on a bottom surface | 4 |
| Variable speed zone cooling controller | 5 |
| A power source | 6 |
| Temperature sensor Interface | 7 |
| Fan Motor | 8 |
| Fan Motor power cable | 8s |
| Cooling System | 10 |

1. A modular zone cooling system, comprising:
a cooling panel having an air permeable mesh on a top surface and an air permeable mesh on a corresponding bottom surface, said cooling panel comprised of a plurality of zones;
at least one fan in each of the plurality of zones;
at least one temperature sensor disposed in each of the plurality of zones;
at least one fan disposed in each of the plurality of zones; and
a controller fixedly attached to the cooling panel and further coupled to each of the temperature sensors and each of the fans, wherein
the controller is configured to receive signals from each of the temperature sensors and control speed of each of the fans according to a predetermined schedule.

2. The modular zone cooling system of claim 1, further comprising coupling members configured to couple the modular zone cooling systems in a modular format, wherein each of the modular zone cooling system is configured to be controlled individually.

3. The modular zone cooling system of claim 1, said sensors are temperature sensors that are positioned according to a predetermined placement so that there is at least one sensor in every zone of the said modular cooling system.

4. The modular zone cooling system of claim 1, said fans configured to function at a plurality of speeds and are positioned according to a predetermined placement such that there is at least one fan in every zone of the cooling system.

5. The modular zone cooling system of claim 1, said controller configured to operate said at a plurality of speeds.

6. The modular zone cooling system of claim 5, said controller configured to modulate the speed of said fan.
